(19) United States
(12) Patent Application Publication
(10) Pub. No.: US 2017/0110440 A1
(43) Pub. Date: Apr. 20, 2017

(54) SEMICONDUCTOR PACKAGE AND METHOD FOR MANUFACTURING SAME

(71) Applicant: SAMSUNG ELECTRONICS CO., LTD., SUWON-SI (KR)

(72) Inventors: HYUNG-SUN JANG, UIWANG-SI (KR); GA-YOUNG KIM, CHEONAN-SI (KR)

(21) Appl. No.: 15/245,306

(22) Filed: Aug. 24, 2016

(30) Foreign Application Priority Data
Oct. 16, 2015 (KR) 10-2015-0144617

(51) Int. Cl. H01L 25/065; H01L 23/48; H01L 23/31

(52) U.S. Cl. CPC H01L 25/0657; H01L 23/3135; H01L 23/481; H01L 2224/0237; H01L 2224/0401; H01L 2224/05025; H01L 2224/05083; H01L 2224/05166; H01L 2224/05147; H01L 2225/06517; H01L 2225/06548; H01L 2225/06513; H01L 2224/16227; H01L 2224/16145

(57) ABSTRACT

Provided are a semiconductor package and method for manufacturing the same. The semiconductor package includes a first semiconductor chip. A first mold layer is disposed on sidewalls of the first semiconductor chip. A second mold layer is disposed on an upper surface of the first mold layer. A first lower via hole penetrates the first mold layer. A first upper via hole penetrates the second mold layer. A first metal pad is disposed between the first upper via hole and the first lower via hole.

### CROSS-REFERENCE TO RELATED APPLICATION

This application claims priority under 35 USC §119 to Korean Patent Application No. 10-2015-0144617, filed on Oct. 16, 2015 in the Korean Intellectual Property Office, the disclosure of which is incorporated by reference herein in its entirety.

### TECHNICAL FIELD

The present disclosure relates to a semiconductor package, and more particularly to a method for manufacturing the same.

### DISCUSSION OF RELATED ART

Electronic devices may be lightweight, small, high speed, multi-functional and high performance devices provided at a relatively low cost. Electronic devices may be manufactured by a multi-chip stacked package technique or a system-in package technique. The multi-chip stacked package technique or the system-in package technique may include forming a through-via.

With the progression of miniaturization of semiconductor devices, an interval between through-vias may be relatively small. However, closely spaced through-vias may result in a conduction failure between the components of a semiconductor package.

### SUMMARY

One or more exemplary embodiments of the present inventive concept may provide a semiconductor package including a precise via reducing or preventing conduction failure between semiconductor components.

One or more exemplary embodiments of the present inventive concept may provide a method for manufacturing a semiconductor package including a precise via reducing or preventing conduction failure between semiconductor components.

According to an exemplary embodiment of the present inventive concept, a semiconductor package includes a first semiconductor chip. A first mold layer is disposed on sidewalls of the first semiconductor chip. A second mold layer is disposed on an upper surface of the first mold layer. A first lower via hole penetrates the first mold layer. A first upper via hole penetrates the second mold layer. A first metal pad is disposed between the first upper via hole and the first lower via hole. The first metal pad at least partially overlaps the first upper via hole and the first lower via hole.

An upper via may substantially fill the interior of the first upper via hole. A lower via may substantially fills the interior of the first lower via hole.

A redistribution layer may be electrically connected to the first upper via hole and may be connected to the top of the second mold layer.

The first upper via hole may have a tapered shape in which a width of a lower surface of the first upper via hole is wider than a width of an upper surface of the first upper via hole.

A redistribution layer may substantially fills an interior of the first upper via hole and may extend above an upper surface of the second mold layer.

The first metal pad may include a barrier layer, an adhesive layer disposed on the barrier layer, and a plating layer disposed on the adhesive layer.

The barrier layer may include titanium, and the adhesive layer may include copper.

A metal post may be disposed on the first metal pad and may fill the first upper via hole.

A width of the metal post may be substantially the same as a width of the first metal pad.

The metal post may be disposed on the first metal pad.

A second semiconductor chip may be disposed on the second mold layer. A substrate may be disposed under the first semiconductor chip. The second semiconductor chip may be electrically connected to a via that fills the first upper via hole.

A second metal pad may be disposed on the first mold layer. The second metal pad may be spaced apart from the first metal pad. A second lower via hole that at least partially overlaps the second metal pad may penetrate the first mold layer. A second upper via hole that at least partially overlaps the second metal pad may penetrate the second mold layer.

According to an exemplary embodiment of the present inventive concept, a semiconductor package includes a first semiconductor chip. A first mold layer is disposed on sidewalls of the first semiconductor chip. The first mold layer includes a lower via hole penetrating the first mold layer. A second mold layer is adhered to the first mold layer. The second mold layer includes an upper via hole penetrating the second mold layer. A metal pad is disposed between the first mold layer and the second mold layer and connects the lower via hole with the upper via hole.

A second semiconductor chip may be disposed on the second mold layer. The second semiconductor chip may be electrically connected to a via that fills the upper via hole.

An upper via may fill the upper via hole, and a lower via may fill the lower via hole. The upper via hole and the lower via hole may be electrically connected via the metal pad.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a diagram of a semiconductor package according to an exemplary embodiment of the present inventive concept;

FIGS. 2a to 2b are partially enlarged views of the semiconductor package of FIG. 1;

FIG. 3 is a diagram of a semiconductor package according to an exemplary embodiment of the present inventive concept;

FIGS. 4 and 5 are diagrams of a semiconductor package according to an exemplary embodiment of the present inventive concept;

FIG. 6 is a block diagram of a System on Chip (SoC) that includes a semiconductor package according to an exemplary embodiment of the present inventive concept;

FIG. 7 is a block diagram of an electronic system including a semiconductor package and a System on Chip (SoC) according to an exemplary embodiment of the present inventive concept;

FIGS. 8 to 10 are exemplary semiconductor systems to which a semiconductor package including a semiconductor chip according an exemplary embodiment of the present inventive concept may be applied; and

FIGS. 11 to 17 are intermediate step diagrams illustrating a method for manufacturing a semiconductor package according to an exemplary embodiment of the present inventive concept.

### DETAILED DESCRIPTION OF THE EMBODIMENTS

Aspects of the present inventive concept and methods of accomplishing the same will be described in more detail below with reference to the accompanying drawings, in which some exemplary embodiments are shown. The present inventive concept may, however, be embodied in many different forms and should not be construed as being limited to the embodiments set forth herein. In the specification and drawings, the thickness of layers and/or regions may be exaggerated for clarity.

It will be understood that when an element or layer is referred to as being “on” or “connected to” another element or layer, it may be directly on or connected to the other element or layer or intervening elements or layers may be present. Like reference numbers may refer to like elements throughout the specification and drawings.

Spatially relative terms, such as “beneath,” “below,” “lower,” “above,” and “upper” may be used herein to describe one element or feature's relationship to another element(s) or feature(s). It will be understood that the spatially relative terms may encompass different orientations of the device in use or operation in addition to the orientation depicted in the figures.

It will be understood that, although the terms first, second, etc. may be used herein to describe various elements, these elements should not be limited by these terms.

The present inventive concept may be described with reference to perspective views, cross-sectional views, and/or plan views, in which exemplary embodiments of the present inventive concept are shown. Thus, the profile of an exemplary view may be modified according to manufacturing techniques and/or allowances.

In one or more exemplary embodiments of the present inventive concept, a substrate may be described as being a circular wafer as an example. However, the present inventive concept is not limited thereto and may be applicable to wafers of various shapes including a square, for example.

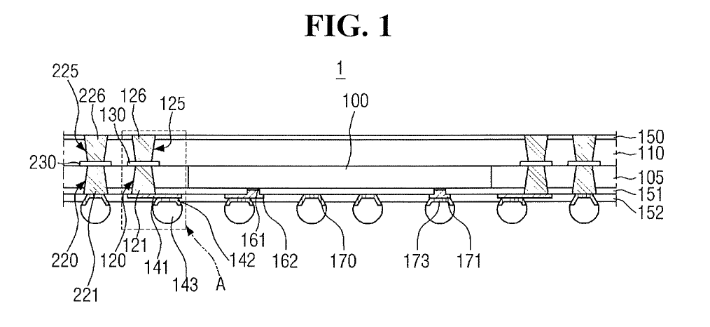

FIG. 1 is a diagram of a semiconductor package according to an exemplary embodiment of the present inventive concept.

Referring to FIG. 1, a semiconductor package 1 may include a first semiconductor chip 100, a first mold layer 105, a second mold layer 110, first and second lower via holes 120 and 220, first upper via holes 125 and 225, first and second lower vias 121 and 221, first and second upper vias 126 and 226, a first metal pad 130 and a second metal pad 230.

The first semiconductor chip 100, for example, may be a memory chip or a logic chip. When the first semiconductor chip 100 is a memory chip or a logic chip, the first semiconductor chip 100 may be variously designed in consideration of the operations to be performed. When the first semiconductor chip 100 is a memory chips, the memory chip may be, for example, a non-volatile memory chip. For example, the memory chip may be a flash memory chip. For example, the memory chip may be a NAND flash memory chip or a NOR flash memory chip. However, exemplary embodiments of the present inventive concept are not limited thereto, and the first semiconductor chip 100 may be any desired semiconductor chip.

In some exemplary embodiments of the present inventive concept, the memory chip may be a volatile memory chip. For example, the memory chip may be a random access memory (DRAM), a static random access memory (SRAM), and an embedded RAM.

When the first semiconductor chip 100 is a logic chip, the logic chip may include a central processing unit (CPU) and a graphics processing unit (GPU).

The first mold layer 105 may cover the sidewalls of the first semiconductor chip 100. The first mold layer 105 may include an epoxy molding compound (EMC).

Although the first mold layer 105 may be substantially the same height as the first semiconductor chip 100, exemplary embodiments of the present inventive concept are not limited thereto. The first mold layer 105 may be higher than the first semiconductor chip 100, and may cover the upper surface of the first semiconductor chip 100. The first mold layer 105 may be lower than the first semiconductor chip 100 and may cover only a part of the sidewall of the first semiconductor chip 100.

The first mold layer 105 may include a first lower via hole 120 that penetrates the first mold layer 105.

The second mold layer 110 may cover the upper surface of the first mold layer 105. The second mold layer 110 may be formed substantially in the same manner as the first mold layer 105. The second mold layer 110 may have a sufficient thickness such that the semiconductor package 1 is not bent, when separating the first semiconductor chip 100 from the carrier frame, in a process of manufacturing the semiconductor package 1. A process of manufacturing a semiconductor package according to some exemplary embodiments of the present inventive concept will be described in more detail below.

The second mold layer 110 may include the first upper via hole 120 that penetrates the second mold layer 110.

The first metal pad 130 may be disposed between the first mold layer 105 and the second mold layer 110. The first metal pad 130 may overlap at least a part of the first lower via hole 120 and the first upper via hole 125. The first metal pad 130 may be electrically connected to the lower via 121 and the upper via 126. The lower via 121 and the upper via 126 may be electrically connected to each other via the first metal pad 130.

The first metal pad 130 may be surrounded by the first mold layer 105 and the second mold layer 110, and need not be exposed to the outside of the semiconductor package.

The lower via 121 and the upper via 126 may include a conductive material. A metal included in the lower via 121 and the upper via 126 may include, for example, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), or zirconium (Zr).

Each of the first lower via hole 120 and the first upper via hole 125 may be formed by laser-etching of the first mold layer 105 and the second mold layer 110.

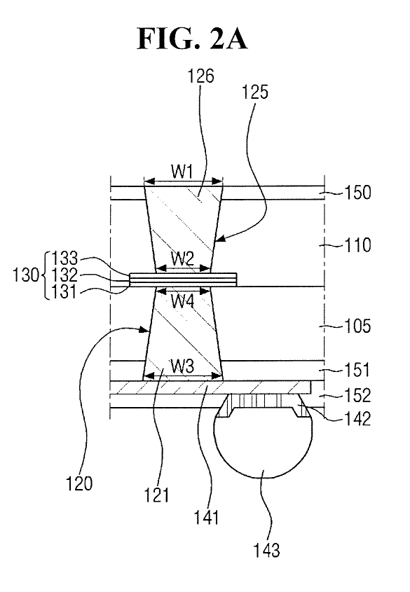

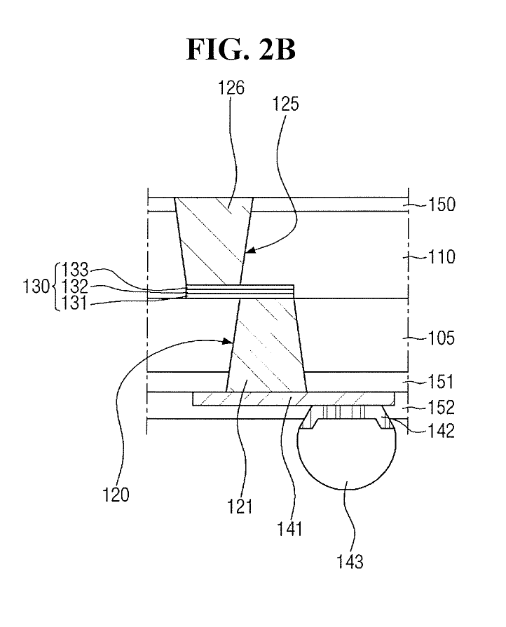

FIGS. 2a and 2b are partially enlarged views of the semiconductor package of FIG. 1.

Referring to FIGS. 2a and 2b, the first upper and lower via holes 120 and 125 and the first metal pad 130 of the semiconductor package 1 will be described in more detail below.

The first upper via hole 125 may have a tapered shape. That is, an uppermost width w1 of the first upper via hole 125 may be formed to be wider than a lowermost width w2 of the first upper via hole 125.

Similarly, a lowermost width w3 of the first upper via hole 125 may be wider than an uppermost width w4, and the first upper via hole 125 may have a tapered shape.

The first metal pad 130 may include a barrier layer 131, an adhesive layer 132 and a plating layer 133.

The barrier layer 131 may be closer to the upper surfaces of the first mold layer 105 and the first lower via hole 120 than the adhesive layer 132 and the plating layer 133. The barrier layer 131 may be in direct contact with the upper surfaces of the first mold layer 105 and the first lower via 121 disposed in the first lower via hole 120.

The barrier layer 131, for example, may be formed by sputtering titanium, but exemplary embodiments of the present inventive concept are not limited thereto. The barrier layer 131 may serve as an etching stop film, when laser-etching the first mold layer 105.

The adhesive layer 132 may be disposed on the barrier layer 131. The adhesive layer 132 may adhere the barrier layer 131 to the plating layer 133. The adhesive layer 132, for example, may be formed by sputtering copper, but exemplary embodiments of the present inventive concept are not limited thereto.

The plating layer 133 may be disposed on the adhesive layer 132. The plating layer 133 may be formed by plating a copper on the adhesive layer 132, but exemplary embodiments of the present inventive concept are not limited thereto.

Referring to FIG. 2a, the first lower via hole 120 and the first upper via hole 125 may be substantially aligned and may be substantially symmetrical with regard to the first metal pad 130.

Referring to FIG. 2b, the first lower via hole 120 and the first upper via hole 125 may be shifted from each other rather than being aligned with each other. That is, in the process of forming the first lower via hole 120 and the first upper via hole 125 the position of the laser etching may be shifted, and thus, the upper surface of the first lower via hole 120 and the lower surface of the first upper via hole 125 may be formed to not overlap each other. In this case, when the first metal pad 130 is not formed, the first lower via hole 120 and the first upper via hole 125 might not be electrically connected to each other.

The first metal pad 130 may be formed to at least partially overlap the first lower via hole 120 and the first upper via hole 125. Thus, even when a misalignment between the first lower via hole 120 and the first upper via hole 125 occurs, the first metal pad 130 may electrically connect the first lower via hole 120 and the first upper via hole 125. Thus, the product reliability of the semiconductor package 1 may be increased.

By forming the first lower via hole 120 and the first upper via hole 125 that penetrate each of the first mold layer 105 and the second mold layer 110 in separate processes, it may be possible to reduce or prevent misalignment and defective shapes of the first lower via hole 120 and the first upper via hole 125.

When forming the via hole that penetrates the first mold layer 105 and the second mold layer 110 at substantially the same time, the depth of the via hole that penetrates the first mold layer 105 and the second mold layer 110 may be substantially the same as the sum of the thicknesses of the first mold layer 105 and the second mold layer 110. The formation depths of the first lower via hole 120 and the first upper via hole 125 according to an exemplary embodiment of the present inventive concept may have substantially the same depths as the thicknesses of the first mold layer 105 and the second mold layer 110, respectively. The depths may each be about half of the depth of the via hole penetrating both the first mold layer 105 and the second mold layer 110.

The smaller the penetration depths of the via holes that penetrate the first mold layer 105 and the second mold layer 110 are, the smaller the amount of the mold layer removed during the laser etching may be. Thus, the possibility of the formation failure of the via hole may be reduced. Thus, by forming the first lower via hole 120 and the first upper via hole 125 in two separate steps, the product reliability of the semiconductor package 1 may be increased.

Referring to FIG. 1, a redistribution line 141 may be disposed on the first lower via 121 that fills the first lower via hole 120. The redistribution line 141 may electrically connect the first lower via 121 and a solder bump 143. The redistribution line 141 may extend above the lower surface of the first mold layer, and the solder bump 143 may be disposed at a position that does not overlap the first lower via hole 120.

The redistribution line 141 may include a same material as a material included in the lower and upper vias 121 and 126, but exemplary embodiments of the present inventive concept are not limited thereto.

A metal layer 142 may be disposed on the redistribution line 141. The metal layer 142 may be an under bump metallurgy (UBM) bump that serves as an adhesive layer, an anti-diffusion layer and a wetting layer. Specifically, while the solder bump 143 for connection with an external terminal is directly formed on the exposed redistribution line 141, the stress may be concentrated between the redistribution layer 141 and the bump that are materials different from each other, and thus, a phenomenon in which the solder bump 143 is not well adhered on the redistribution line 141 may occur. Further, even if the redistribution line 141 and the solder bump 143 are bonded, since the stress may be concentrated on the bonding surface between the redistribution line 141 and the solder bump 143, the bonding surface may be separated due to fatigue caused by the operation of the semiconductor package, and a mechanical failure may occur.

The metal layer 142, for example, may have a multilayer structure, which may be formed by depositing various metals such as chromium (Cr), copper (Cu), nickel (Ni), titanium-tungsten (TiW) and nickel-vanadium (NiV) through sputtering.

The second metal pad 230 may be formed on the first mold layer 105 and may be spaced apart from the first metal pad 130. The second metal pad 230 may be formed by substantially the same method as the first metal pad 130.

The second lower via hole 220 may be formed through the first mold layer 105 and may partially overlap the second metal pad 230. The second upper via hole 225 may be formed through the second mold layer 110 and may at least partially overlap the second metal pad 230. The second lower via hole 220 and the second upper via hole 225 may be electrically connected to each other via the second metal pad 230.

A lower pad 161 may be disposed at the bottom of the first semiconductor chip 100. The lower pad 161 may be connected with a redistribution line 162 or a bonding pad 171 to electrically connect the first semiconductor chip 100 with anther circuit element disposed at the bottom of the semiconductor chip 100. Although FIG. 1 illustrates a case where the two lower pads 161 are formed, exemplary embodiments of the present inventive concept are not limited thereto, and any desired number of lower pads may be formed.

A first lower passivation film 151 may be formed at the bottom of the first semiconductor chip 100. The first lower passivation film 151 may expose the first and second lower vias 120 and 220 and the lower pad 161. The first lower passivation film 151 may include an insulating material which may protect the bottom of the first semiconductor chip 100. For example, the insulating film may include an oxide film or a nitride film.

Upper passivation film 150 may be disposed on the second mold layer 110. The upper passivation film 150 may expose the first and second upper vias 125 and 225. The upper passivation film 150 may include an insulating material which may protect the second mold layer 120. For example, the upper passivation film 150 may include an oxide film or a nitride film.

A second lower passivation film 152 may be disposed on the first lower passivation film 151. The second lower passivation film 152 may protect the redistribution lines 141 and 162. The second lower passivation film 152 may expose the metal layers 142, 170 and 173.

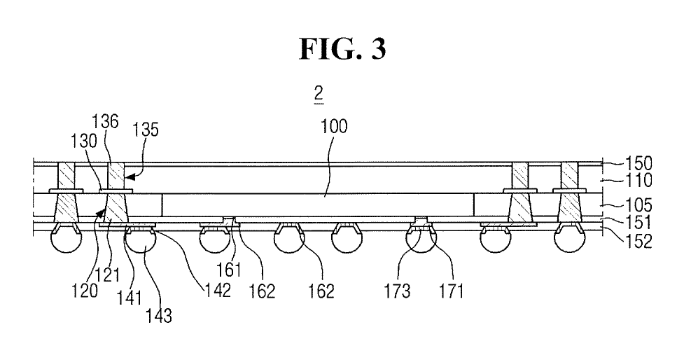

FIG. 3 is a diagram illustrating a semiconductor package according to an exemplary embodiment of the present inventive concept. The components illustrated in FIG. 3 may be substantially the same as the components described above with reference to FIGS. 1, 2A and 2B, and thus duplicative descriptions may be omitted.

Referring to FIG. 3, a semiconductor package 2 may be different from the semiconductor package 1. The third upper via hole 135 may have a shape with a substantially constant width. That is, the side walls of the third upper via hole 135 might not be tapered.

A first metal post 136 may fill the third upper via hole 135. The first metal post 136 may have substantially the same width as the first metal pad 130. The first metal pad 130 and the first metal post 136 may be formed at the same level. The first metal pad 130 and the first metal post 136 may be formed by the same manufacturing process. That is, when forming the plating layer 133 of the first metal pad 130, by forming the plating layer 133 at the height of the first metal post 136, the first metal post 136 may be formed.

The first metal post 136 may include a conductive material, and may electrically connect the first lower via 121, the first metal pad 130, and other circuit elements disposed on the second mold layer 110 to each other.

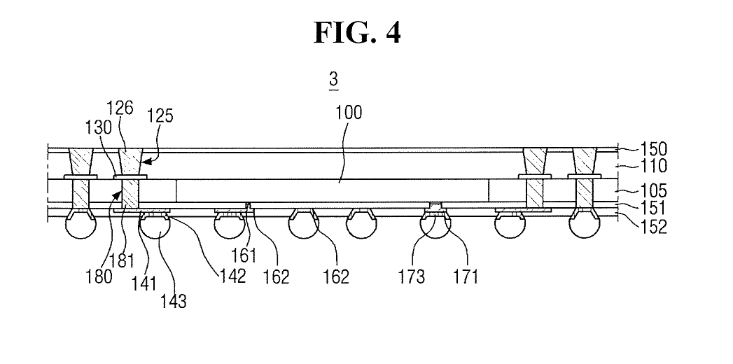

FIG. 4 is a diagram illustrating a semiconductor package according to an exemplary embodiment of the present inventive concept.

Referring to FIG. 4, a semiconductor packages 3 may include a second metal post 181 that fills a third lower via hole 180. The third lower via hole 180 may have a non-tapered shape.

The second metal post 181 may be formed, by laser-etching the first mold layer 105 on the first metal pad 130 to form the third lower via hole 180, and by filling the third lower via hole 180 with a conductive material.

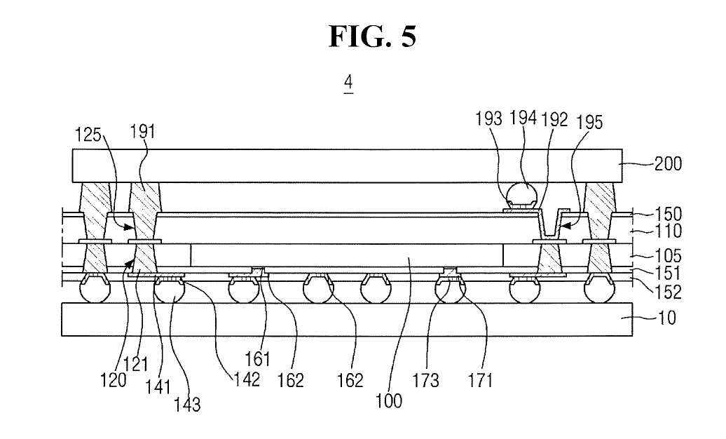

FIG. 5 is a diagram illustrating a semiconductor package according to an exemplary embodiment of the present inventive concept.

Referring to FIG. 5, a semiconductor package 4 may include a second semiconductor chip 200 disposed on the first semiconductor chip 100, and a substrate 10 disposed below the first semiconductor chip 100.

The substrate 10 may be a packaging substrate, and for example, may be a printed circuit board (PCB) or a ceramic substrate. The substrate 10 may be electrically connected to the first semiconductor chip 100 through the solder bump 143.

The second semiconductor chip 200 may be disposed on the first semiconductor chip 100 and may be electrically connected to the first semiconductor chip 100. The first semiconductor chip 100 and the second semiconductor chip 200 may be disposed on the substrate 10 and may be sequentially laminated. The first semiconductor chip 100 and the second semiconductor chip 200 may be electrically connected to each other via a solder 191 that fills the first upper via hole 125. The second semiconductor chip 200 may be electrically connected to the first semiconductor chip 100 through a redistribution line 192 that partially fills the fourth upper via hole 195, and a metal layer 193 and a solder bump 194 each formed on the redistribution line 192.

A connection form between the first semiconductor chip 100 and the second semiconductor chip 200 illustrated in FIG. 5 is an example, and exemplary embodiments of the present inventive concept are not limited thereto.

The second semiconductor chip 200 may be a logic chip or a memory chip. For example, when the first semiconductor chip 100 is a logic chip, the second semiconductor chip 200 may be a memory chip. For example, when the first semiconductor chip 100 is a memory chip, the second semiconductor chip 200 may be a logic chip.

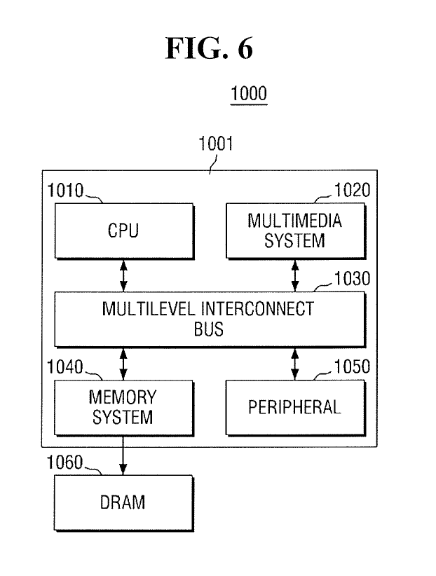

FIG. 6 is a block diagram of a System on Chip (SoC) that includes a semiconductor package according to an exemplary embodiment of the present inventive concept.

Referring to FIG. 6, an SoC 1000 may include an application processor 1001 and a DRAM 1060.

The application processor 1001 may include a central processing unit 1010, a multimedia system 1020, a multilevel connection bus 1030, a memory system 1040 and a peripheral circuit 1050.

The central processing unit 1010 may perform operations for driving the SoC 1000. In some exemplary embodiments of the present inventive concept, the central processing unit 1010 may have a multi-core environment that includes multiple cores.

The multimedia system 1020 may be used to perform various multimedia functions in the SoC system 1000. The multi-media system 1020 may include a 3D engine module, a video codec, a display system, a camera system, and a post-processor.

The multilevel connection bus 1030 may be used to perform the mutual data communication of the central processing unit 1010, the multimedia system 1020, the memory system 1040 and the peripheral circuit 1050. In some exemplary embodiments of the present inventive concept, the multilevel connection bus 1030 may have a multilayer structure. Specifically, as an example of the multilevel connection bus 1030, but not limited to, a multilayer advanced high-performance bus (AHB) or a multilayer advanced extensible interface (AXI) may be used.

The memory system 1040 may provide an environment for the application processor 1001 to be connected to an external memory (e.g., the DRAM 1060) and operate at relatively high speed. In some exemplary embodiments of the present inventive concept, the memory system 1040 may include a separate controller (e.g., a DRAM controller) to control the external memory (e.g., the DRAM 1060).

The peripheral circuit 1050 may provide an environment for the SoC system 1000 to smoothly connect to an external device (e.g., a mainboard). Thus, the peripheral circuit 1050 may include various interfaces that enable the external device connected to the SoC system 1000 to be compatible with the SoC system 1000.

The DRAM 1060 may function as an operating memory for the operation of the application processor 1001. In some exemplary embodiments of the present inventive concept, the DRAM 1060 may be disposed outside the application processor 1001. For example, the DRAM 1060 may be packaged with the application processor 1001 in the form of package on package (PoP).

As at least one of the components of the SoC system 1000, one of the semiconductor circuits according to the exemplary embodiments of the present inventive concept described herein may be adopted. For example, the application processor 1001 may include the first semiconductor chip (e.g., the first semiconductor chip 100), the DRAM 1060 may include the second semiconductor chip (e.g., the second semiconductor chip 200), and the semiconductor chips may be packaged in a PoP form.

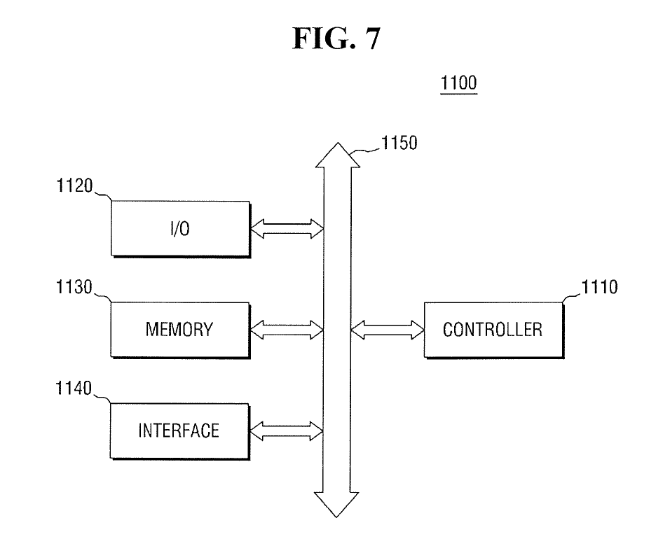

FIG. 7 is a block diagram of an electronic system including a semiconductor package and a System on Chip (SoC) according to an exemplary embodiment of the present inventive concept.

Referring to FIG. 7, the electronic system 1100 according to an exemplary embodiment of the present inventive concept may include a controller 1110, an input/output (I/O) device 1120, a memory device 1130, an interface 1140 and a bus 1150. The controller 1110, the I/O device 1120, the memory device 1130 and/or the interface 1140 may be connected to one another through the bus 1150. The bus 1150 corresponds to a path through which the data are moved.

The controller 1110 may include at least one of a microprocessor, a digital signal processor, a microcontroller and logic devices capable of performing similar functions to the elements. The I/O device 1120 may include a keypad, a keyboard, and a display device. The memory device 1130 may store data and/or commands. The interface 1140 may serve to transmit data to or receive data from a communication network. The interface 1140 may be a wired or wireless interface. For example, the interface 1140 may include an antenna or a wired or wireless transceiver.

The electronic system 1100 may be an operating memory increasing the operation speed of the controller 1110, and may include a high-speed DRAM or SRAM.

The semiconductor package according to an exemplary embodiment of the present inventive concept may be included in the memory device 1130 or may be included as a part of the controller 1110, or the I/O device 1120.

The electronic system 1100 may be included in any desired electronic products capable of transmitting or receiving information in a wireless environment, such as a personal digital assistant (PDA), a portable computer, a web tablet, a wireless phone, a mobile phone, a digital music player and a memory card.

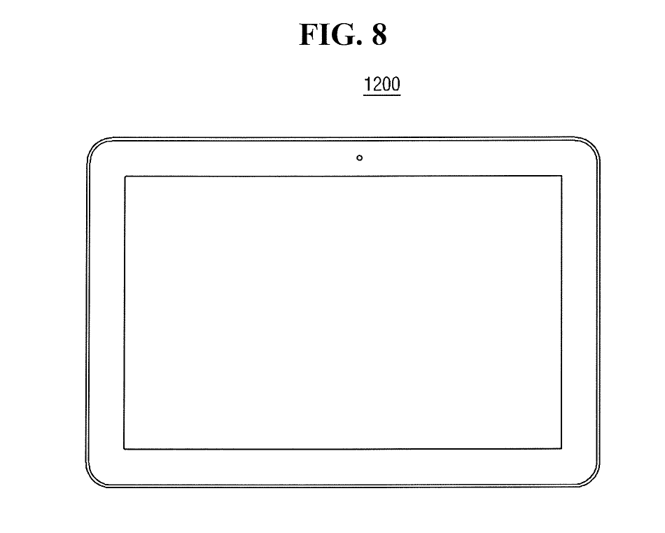

FIGS. 8 to 10 are exemplary semiconductor systems to which a semiconductor package including a semiconductor chip according an exemplary embodiment of the present inventive concept may be applied.

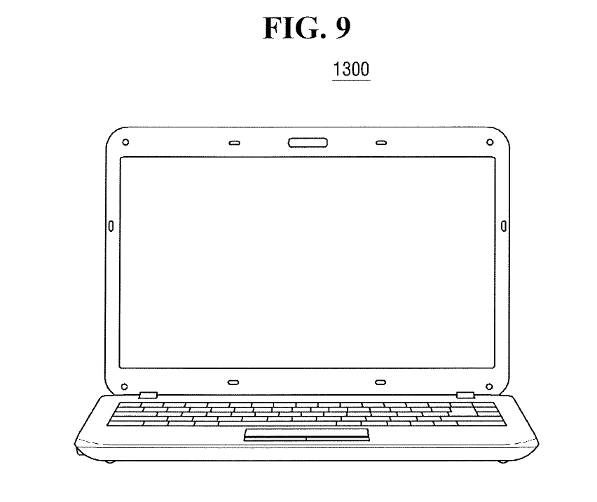

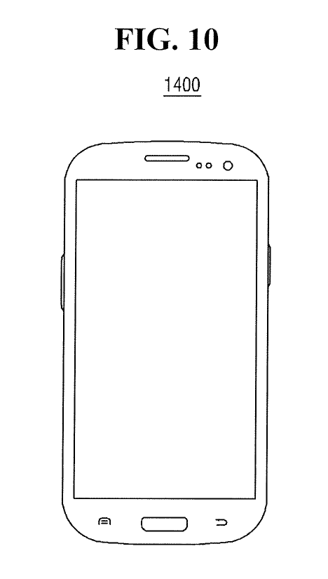

FIG. 8 illustrates a tablet personal computer (PC) 1200, FIG. 9 illustrates a notebook computer 1300, and FIG. 10 illustrates a smart phone 1400. At least one of the semiconductor packages according to an exemplary embodiment of the present inventive concept may be used in the tablet PC 1200, the notebook computer 1300, and the smart phone 1400.

Further, it is obvious to a person skilled in the art that the semiconductor packages according to some exemplary embodiments of the present inventive concept may also be applied to other IC devices other than those set forth herein.

That is, while only the tablet PC 120, the notebook computer 1300 and the smart phone 1400 have been described above as examples of a semiconductor system according to some exemplary embodiments of the present inventive concept, exemplary embodiments of the present inventive concept are not limited thereto.

In some exemplary embodiments of the present inventive concept, the semiconductor system may be provided as a computer, an Ultra Mobile PC (UMPC), a work station, a net-book computer, a personal digital assistant (PDA), a portable computer, a wireless phone, a mobile phone, an e-book, a portable multimedia player (PMP), a portable game console, a navigation device, a black box, a digital camera, a 3-dimensional television set, a digital audio recorder, a digital audio player, a digital picture recorder, a digital picture player, a digital video recorder, or a digital video player.

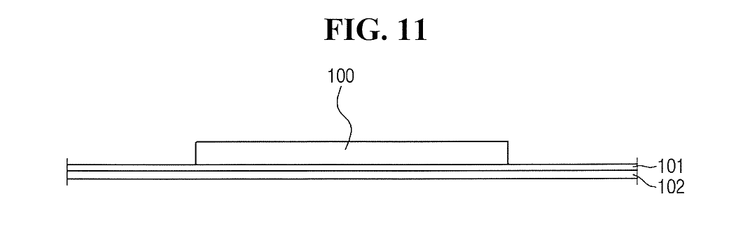

FIGS. 11 to 17 are intermediate step diagrams illustrating a method for manufacturing a semiconductor package according to an exemplary embodiment of the present inventive concept.

Referring to FIG. 11, the first semiconductor chip 100 may be attached to the top of a carrier frame 102. The first semiconductor chip 100 may be attached to the top of the carrier frame 102 through a tape 101.

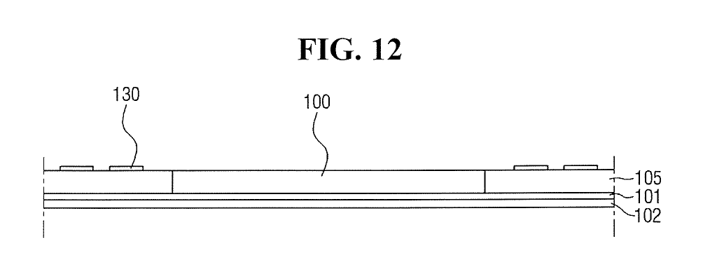

Referring to FIG. 12, the first mold layer 105 may be formed to cover the sidewalls of the first semiconductor chip 100, and the first metal pad 130 may be formed on the first mold layer 105.

The first mold layer 105 may be formed on the tape 101, for example, by molding an EMC and performing a curing process.

The first mold layer 105 may expose the upper surface of the first semiconductor chip 100, but, exemplary embodiments of the present inventive concept are not limited thereto. The first mold layer 105 may be formed to cover the upper surface of the first semiconductor chip 100.

The first metal pad 130, for example, may be formed through the following process. The barrier layer (e.g., barrier layer 131) and the adhesive layer (e.g., adhesive layer 132) may be sequentially sputtered on the first mold layer 105, and the upper surface of the adhesive layer (e.g., the adhesive layer 132) may be plated to form a plating layer (e.g., plating layer 133). Thus, an etching mask may be formed on the plating layer 132, and by etching the barrier layer (e.g., barrier layer 131), the adhesive layer (e.g., adhesive layer 132) and the plating layer (e.g., plating layer 133) which are not covered with the etching mask, the first metal pad 130 may be formed.

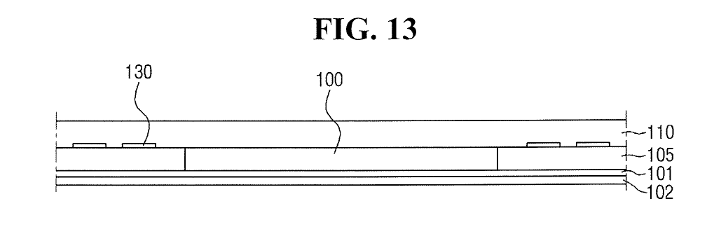

Referring to FIG. 13, the second mold layer 110 may be formed to cover the upper surfaces of the first molding layer 105 and the first metal pad 130. The second mold layer 110 may be formed, for example, by molding the EMC on the first mold layer 105 and the first metal pad 130 and by performing a curing process.

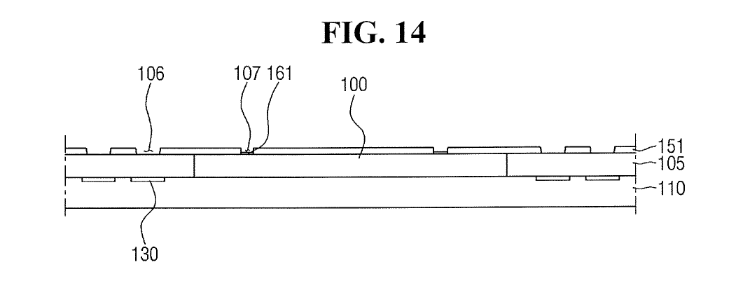

Referring to FIG. 14, the first mold layer 105 and the first semiconductor chip 100 may be peeled off from the tape (e.g., tape 101), and a first lower surface passivation layer 151 may be formed on the lower surfaces of the first semiconductor chip 100 and the first mold layer 105.

Since the first mold layer 105 and the second mold layer 110 may be formed together to have a sufficient thickness, when the first mold layer 105 and the first semiconductor chip 100 are peeled off from the tape (e.g., tape 101), bending of the first semiconductor chip 100 may be reduced or prevented.

The first lower surface passivation layer 151 may expose the lower pad 161, and may cover the lower surfaces of the first semiconductor chip 100 and the first mold layer 105 to form a first trench 106. The first trench 106 may be formed at a position where the first lower via hole (e.g., first lower via hole 120) is formed in the semiconductor package according to an exemplary embodiment of the present inventive concept.

The first lower surface passivation layer 151 may be formed to be higher than the lower pad 161 to form a second trench 107.

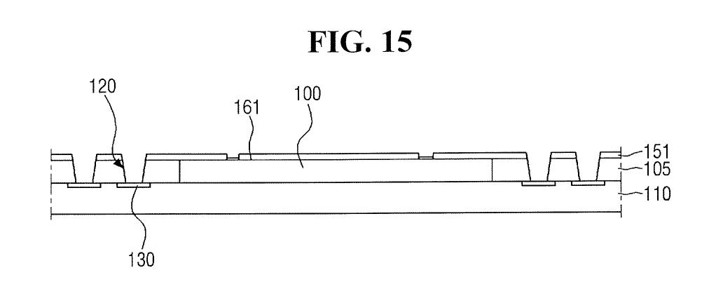

Referring to FIG. 15, the first mold layer 105 may be etched to foam the first lower via hole 120. The first lower via hole 120 may be formed by laser etching.

FIGS. 14 and 15 illustrate a configuration in which the first lower via hole 120 is formed by forming the first trench 106 in the first lower passivation layer 151, but exemplary embodiments of the present inventive concept are not limited thereto. For example, in some exemplary embodiments of the present inventive concept, the first trench 106 need not be first formed, and the first lower passivation layer 151 and the first mold layer 105 may be substantially simultaneously etched by a laser.

In the etching process of the first lower via hole 120, the first metal pad 130 may serve as an etching stop film.

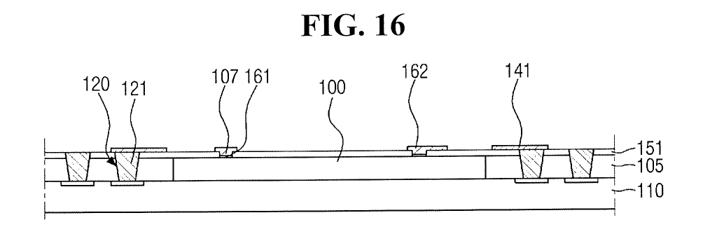

Referring to FIG. 16, the first lower via 121 filling the first lower via hole 120, the redistribution line 141 connected to the first lower via 121, and the redistribution line 162 connected to the lower pad 161 may be formed.

The redistribution lines 141 and 162, for example, may be formed by patterning the metal layer formed on the first lower via 121 and the lower pad 161.

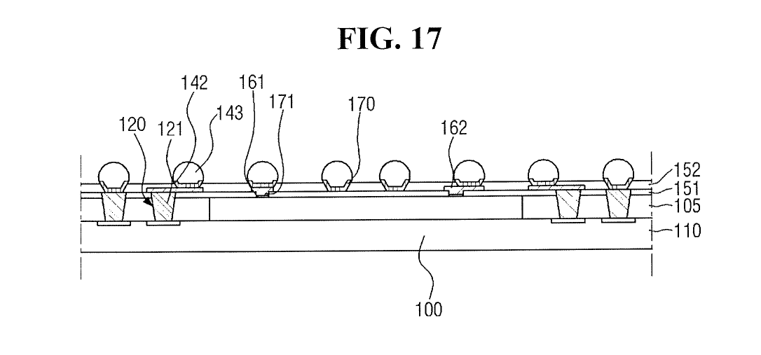

Referring to FIG. 17, the second lower passivation layer 152 and metal layers 142, 170 and 173 may be formed on the first lower passivation layer 151 and the redistribution lines 141 and 162. By forming the solder bump 143 on the metal layers 142, 170 and 173, other circuit components disposed below the first semiconductor chip 100 may be electrically connected to the first semiconductor chip 100.

Referring to FIG. 1 again, the first and second upper via holes 125 and 225 may be formed by etching the second molding layer 110, and the via holes may be filled with the first and second upper vias 126 and 226. When forming the first and second upper via holes 125 and 225, the first and second metal pads 130, 230 may serve as an etching stop film.

As described above according to one or more exemplary embodiments of the present inventive concept, when forming the via holes in the semiconductor package, by separately forming the via holes into the upper and lower via holes 120, 125 of the relatively shallow depth, a formation error of the via having a precise interval may be reduced or eliminated. Thus, the operation reliability of the semiconductor package according to exemplary embodiments of the present inventive concept may be increased.

While the present inventive concept has been particularly shown and described with reference to exemplary embodiments thereof, it will be understood by those of ordinary skill in the art that various changes in form and detail may be made therein without departing from the spirit and scope of the present inventive concept.

What is claimed is:

1. A semiconductor package comprising:
a first semiconductor chip;
a first mold layer disposed on sidewalls of the first semiconductor chip;
a second mold layer disposed on an upper surface of the first mold layer;
a first lower via hole that penetrates the first mold layer;
a first upper via hole that penetrates the second mold layer; and
a first metal pad disposed between the first upper via hole and the first lower via hole, wherein the first metal pad at least partially overlaps the first upper via hole and the first lower via hole.

2. The semiconductor package of claim 1, further comprising:
an upper via that substantially fills the interior of the first upper via hole; and
a lower via that substantially fills the interior of the first lower via hole.

3. The semiconductor package of claim 2, further comprising:
a redistribution line that is electrically connected to the first lower via hole and is connected to the top of the first mold layer.

4. The semiconductor package of claim 1, wherein the first upper via hole has a tapered shape in which a width of a lower surface of the first upper via hole is wider than a width of an upper surface of the first upper via hole.

5. The semiconductor package of claim 1, further comprising:
a redistribution line that substantially fills an interior of the first lower via hole and extends above an upper surface of the first mold layer.

6. The semiconductor package of claim 1, wherein the first metal pad comprises:
a barrier layer,
an adhesive layer disposed on the barrier layer, and
a plating layer disposed on the adhesive layer.

7. The semiconductor package of claim 6, wherein the barrier layer includes titanium, and
the adhesive layer includes copper.

8. The semiconductor package of claim 1, further comprising:
a metal post that is disposed on the first metal pad and fills the first upper via hole.

9. The semiconductor package of claim 8, wherein a width of the metal post is substantially the same as a width of the first metal pad.

10. The semiconductor package of claim 9, wherein the metal post is disposed on the first metal pad.

11. The semiconductor package of claim 1, further comprising:
a second semiconductor chip disposed on the second mold layer; and
a substrate disposed under the first semiconductor chip,
wherein the second semiconductor chip is electrically connected to a via that fills the first upper via hole.

12. The semiconductor package of claim 1, further comprising:
a second metal pad disposed on the first mold layer, wherein the second metal pad is spaced apart from the first metal pad;
a second lower via hole that at least partially overlaps the second metal pad and penetrates the first mold layer; and
a second upper via hole that at least partially overlaps the second metal pad and penetrates the second mold layer.

13. A semiconductor package comprising:
a first semiconductor chip;
a first mold layer disposed on sidewalls of the first semiconductor chip, wherein the first mold layer comprises a lower via hole penetrating the first mold layer;
a second mold layer that is adhered to the first mold layer, wherein the second mold layer comprises an upper via hole penetrating the second mold layer; and
a metal pad that is disposed between the first mold layer and the second mold layer and connects the lower via hole with the upper via hole.

14. The semiconductor package of claim 13, further comprising:
a second semiconductor chip disposed on the second mold layer,
wherein the second semiconductor chip is electrically connected to a via that fills the upper via hole.

15. The semiconductor package of claim 13, further comprising:
an upper via that fills the upper via hole, and a lower via that fills the lower via hole,
wherein the upper via hole and the lower via hole are electrically connected via the metal pad.

16. A semiconductor package comprising:
a semiconductor chip;
a first mold layer disposed on sidewalls of the first semiconductor chip;
a second mold layer disposed on an upper surface of the first mold layer and on an upper surface of the first semiconductor chip;
a lower via hole penetrating the first mold layer;
an upper via hole penetrating the second mold layer, wherein the upper via hole is spaced apart from the lower via hole when viewed from a plan view; and
a metal pad disposed between the first mold layer and the second mold layer, wherein the metal pad at least partially overlaps the lower via hole and the upper via hole.

17. The semiconductor package of claim 16, wherein a redistribution layer fills at least one of the upper via hole and the lower via hole.

18. The semiconductor package of claim 16, wherein at least one of the upper via hole and the lower via hole has a tapered shape.

19. The semiconductor package of claim 16, wherein the metal pad comprises:
a barrier layer,
an adhesive layer disposed on the barrier layer, and
a plating layer disposed on the adhesive layer.

20. The semiconductor package of claim 16, wherein the barrier layer includes titanium, and the adhesive layer includes copper.
